(19) United States
(12) Patent Application Publication
(10) Pub. No.: US 2025/0305136 A1
(43) Pub. Date: Oct. 2, 2025

(54) BATCH TYPE PANEL ATOMIC LAYER DEPOSITION APPARATUS

(71) Applicant: SKY TECH INC., Hsinchu County (TW)

(72) Inventors: JUNG-HUA CHANG, Hsinchu County (TW); CHING-LIANG YI, Hsinchu County (TW)

(21) Appl. No.: 18/616,327

(22) Filed: Mar. 26, 2024

(51) Int. Cl. C23C 16/455; C23C 16/44

(52) U.S. Cl. CPC C23C 16/45544; C23C 16/4408; C23C 16/45555

(57) ABSTRACT

A batch type panel atomic layer deposition apparatus includes a vacuum chamber, a shaft seal device, and a rotary drive assembly. The vacuum chamber includes a front wall, a rear wall, and a peripheral wall. The peripheral wall connects edges of the front wall and the rear wall to form a reaction space therebetween. Concave portions and convex portions are provided on an inner side of the peripheral wall in a staggered configuration. The bottom of each of the concave portions is a planar surface. One end of the shaft seal device is connected to the rear wall. The rotary drive assembly is connected to the other end of the shaft seal device, such that the rotary drive assembly is connected to the vacuum chamber through the shaft seal device to drive the vacuum chamber to rotate about the rotational axis.

### BACKGROUND

### Technical Field

This disclosure relates to a batch type panel atomic layer deposition apparatus for holding a plurality of panels to be processed and performing atomic layer deposition operations on the surfaces of the plurality of panels to be processed in a batch manner.

### Related Art

A nanoparticle is generally defined as a particle that is smaller than 100 nanometers in at least one dimension. Nanoparticles have very different physical and chemical properties from macroscopic substances. In general, the physical properties of a macroscopic substance are not related to its size, but this is not the case with nanoparticles, which have potential applications in fields such as biomedicine, optics and electronics.

A quantum dot is a semiconducting nanoparticle. Currently, this semiconducting nanoparticles under study are II-VI materials, such as ZnS, CdS, CdSe, etc., among which CdSe has attracted the most attention. Quantum dots typically range in size from 2 to 50 nanometers. When a quantum dot is irradiated with ultraviolet light, the electrons in the quantum dot absorb energy to be excited from the valence band to the conduction band. When an excited electron returns from the conduction band to the valence band, it releases energy by emitting light.

The energy gap of a quantum dot is related to its size. A larger size of the quantum dot results a smaller energy gap, and the quantum dot will emit light with a longer wavelength after irradiation. A smaller size of the quantum dot results a larger energy gap, and the quantum dot will emit light with a shorter wavelength after irradiation. For example, quantum dots of 5 to 6 nanometers emit orange or red light, while quantum dots of 2 to 3 nanometers emit blue or green light. Of course the color of light depends on the material composition of the quantum dots.

Light emitting diodes (LEDs) using quantum dots produce light that is close to the continuous spectrum, and at the same time have a high degree of color rendering, which is conducive to improving the light-emitting quality of the LEDs. In addition, the wavelength of the emitted light can be adjusted by changing the size of the quantum dots, making quantum dots the focus of the development of next-generation light-emitting devices and displays.

Although quantum dots have the above advantages and characteristics, they are prone to agglomeration during the manufacturing process. Furthermore, quantum dots have high surface activity and react easily with air and moisture, which shortens the life of quantum dots.

Specifically, the process of making quantum dots into package glue for light emitting diodes (LEDs) may produce an agglomeration effect that reduces the optical properties of the quantum dots. Moreover, after the quantum dots are made into the LED package glue, external oxygen or moisture may still penetrate through the package glue and come into contact with the surface of the quantum dots, resulting in oxidization of the quantum dots and shortening the performance or service life of the quantum dots and LEDs. Surface defects and dangling bonds in quantum dots may also cause non-radiative recombination.

Currently, the industry will form a thin film with a thickness of nanometer scale on the surface of the quantum dots by atomic layer deposition (ALD), or form multiple thin films on the surface of the quantum dots to form a quantum well structure.

Atomic Layer Deposition allows for the formation of films of uniform thickness on a substrate and effective control of film thickness, and is theoretically applicable to three-dimensional quantum dots as well. When a quantum dot is resting on a carrier disk, there are contact points between neighboring quantum dots, making it impossible for the precursor gases of atomic layer deposition to contact these contact points, and resulting in the failure to form a film of uniform thickness on the surface of all the nanoparticles.

### SUMMARY

In view of the above problem, this disclosure presents a batch type panel atomic layer deposition apparatus configured to form a film of uniform thickness on surfaces of the nanoparticles.

This disclosure presents a batch type panel atomic layer deposition apparatus including a vacuum chamber, a shaft seal device, and a rotary drive assembly. The vacuum chamber includes a front wall, a rear wall, and a peripheral wall. The front wall and the rear wall are disposed parallel to each other, the peripheral wall connects edges of the front wall and the rear wall to form a reaction space therebetween. Concave portions and convex portions are provided on an inner side of the peripheral wall in a staggered configuration. The concave portions and the convex portions are arranged in a radial arrangement around a rotational axis. The bottom of each of the concave portions is a planar surface, and the rotational axis is defined to pass through the front wall a rear wall. One end of the shaft seal device is connected to the rear wall along the rotational axis. The rotary drive assembly is connected to the other end of the shaft seal device, such that the rotary drive assembly is connected to the vacuum chamber through the shaft seal device to drive the vacuum chamber to rotate about the rotational axis.

In at least one embodiment, the batch type panel atomic layer deposition apparatus further includes a base. The base includes a setup surface, and the rotary drive assembly is disposed on the setup surface.

In at least one embodiment, the batch type panel atomic layer deposition apparatus further includes a plurality of pipelines, extending in the shaft seal device, and fluidly connected to the vacuum chamber; wherein the plurality of pipelines are stationary and without rotating with the vacuum chamber.

In at least one embodiment, the shaft seal device includes an outer shaft tube and a center shaft tube. The outer shaft tube is rotatably disposed on the setup surface via of a bearing seat, and the outer shaft tube includes a first end, a second end, and an accommodation space. The rotary drive assembly is connected to the first end of the outer shaft tube, and the second end of the outer shaft tube is connected to a rear wall of the vacuum chamber, wherein the rotary drive assembly is configured to rotate the outer shaft tube, so as to drive the vacuum chamber to rotate. The center shaft tube has a tubular space in which the plurality of pipelines extend. The center shaft tube is disposed in the accommodation space, and the outer shaft tube and the center shaft tube are coaxially disposed in the rotational axis. The center shaft tube is stationary without rotating with the outer shaft tube.

In at least one embodiment, the rear wall is provided with a through hole. The center shaft tube protrudes from the second end of the outer shaft tube and is inserted into the through hole to form a rotary seal with the vacuum chamber, and at least one shaft seal is provided between the center shaft tube and the outer shaft tube.

In at least one embodiment, the plurality of pipelines include a gas evacuating pipeline, a reactive gas pipeline, and a purge pipeline. The gas evacuating pipeline is fluidly connected to the reaction space, and configured to remove gas from the reaction space. The reactive gas pipeline is fluidly connected to the reaction space, and configured to transport reactive gas containing reactants to the reaction space. The purge pipeline is fluidly connected to the reaction space, and configured to transport non-participating inert gas as purge gas into the reaction space.

In at least one embodiment, a filter is provided at the end of the center shaft tube connected to the reaction space, the gas evacuating pipeline is fluidly connected to the reaction space via the filter, and evacuate gas from the reaction space via the filter.

In at least one embodiment, the vacuum chamber includes an enclosing wall disposed on a side of the reaction space where the rear wall is disposed and surrounds the through hole.

In at least one embodiment, the batch type panel atomic layer deposition apparatus further includes a heater and a temperature sensor. The heater is disposed in the tubular space for heating the tubular space. The temperature sensor is disposed in the tubular space and configured to detect a temperature of the heater or the tubular space, so as to adjust a heating power of the heater.

In at least one embodiment, the batch type panel atomic layer deposition apparatus further includes a heating device, provided around an outside of the peripheral wall and configured to heat the vacuum chamber and the reaction space.

With the batch type panel atomic layer deposition apparatus of this disclosure, it is possible to perform batch atomic layer thin film deposition on multiple panels to be processed at the same time. The powder used to form part of the film can be effectively agitated and dispersed in the reaction space to form a film of uniform thickness on the surfaces of the panels to be processed.

### BRIEF DESCRIPTION OF THE DRAWINGS

This disclosure will become more fully understood from the detailed description given herein below for illustration only, and thus not limitative of this disclosure; wherein:

FIG. 1 is a perspective view of a batch type panel atomic layer deposition apparatus according to an embodiment of this disclosure.

FIG. 2 is a cross-sectional view of the batch type panel atomic layer deposition apparatus according to the embodiment of this disclosure.

FIG. 3 is a cross-sectional view of the shaft seal device in the embodiment of this disclosure.

FIG. 4 is perspective view of the vacuum chamber in the embodiment of this disclosure.

FIG. 5 is a cross-sectional view of the vacuum chamber in the embodiment of this disclosure.

FIG. 6 is another cross-sectional view of the vacuum chamber in the embodiment of this disclosure.

FIG. 7 is a perspective view of a batch type panel atomic layer deposition apparatus according to another embodiment of this disclosure.

FIG. 8 is a cross-sectional view of the batch type panel atomic layer deposition apparatus according to another embodiment of this disclosure.

### DETAILED DESCRIPTION

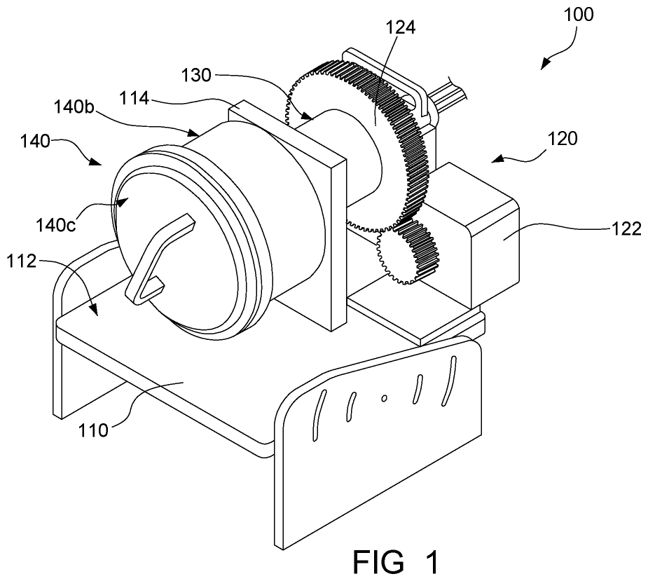

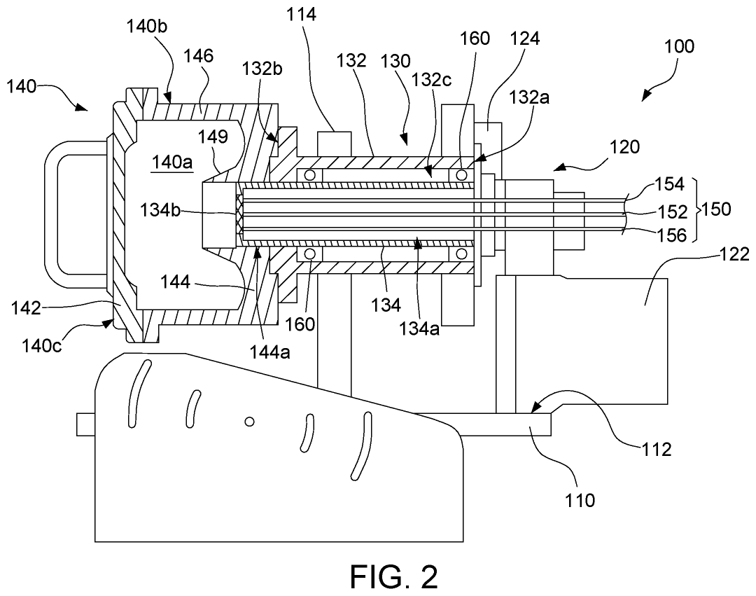

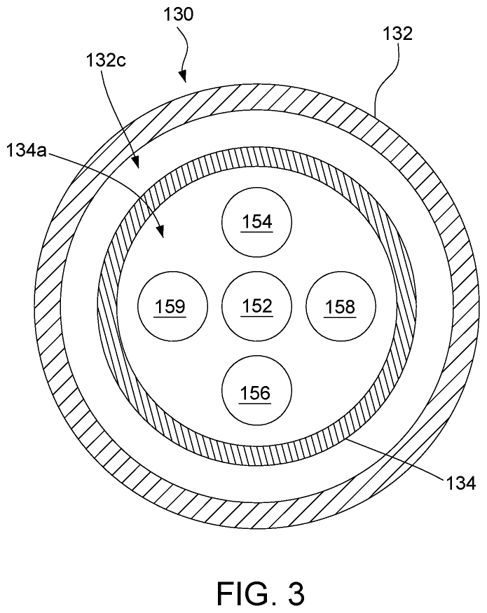

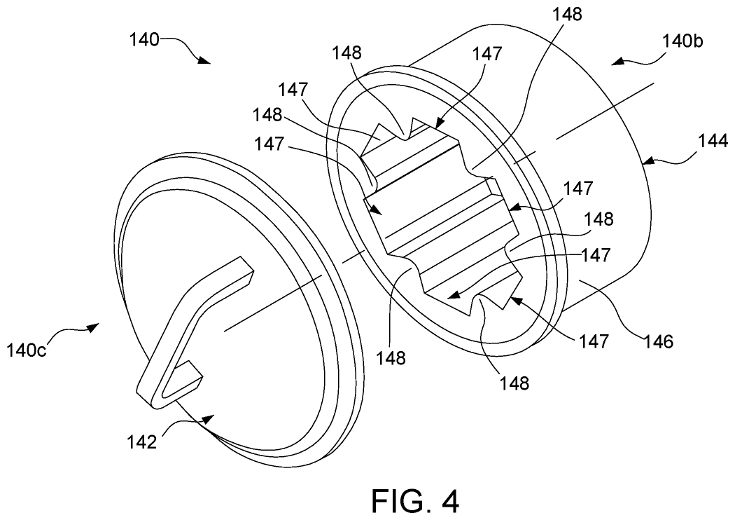

Please refer to FIG. 1, FIG. 2, FIG. 3, and FIG. 4, a batch type panel atomic layer deposition apparatus 100 according to an embodiment of this disclosure is illustrated. As shown in FIG. 1 and FIG. 2, the batch type panel atomic layer deposition apparatus 100 includes a base 110, a rotary drive assembly 120, a shaft seal device 130, a vacuum chamber 140, and a plurality of pipelines 150. The rotary drive assembly 120 is connected to the vacuum chamber 140 through the shaft seal device 130 to drive the vacuum chamber 140 to rotate about a rotational axis.

The plurality of pipelines 150 extend in the shaft seal device 130 and are fluidly connected to vacuum chamber 140. The plurality of pipelines 150 are stationary and without rotating with the vacuum chamber 140.

As shown in FIG. 1, FIG. 2 and FIG. 4, the vacuum chamber 140 includes a front wall 142, a rear wall 144, and a peripheral wall 146. The front wall 142 and the rear wall 144 are disposed parallel to each other. The peripheral wall 146 connects edges of the front wall 142 and the rear wall 144 to form a reaction space 140a therebetween, and the reaction space 140a is configured to contain powder P. The shaft seal device 130 is connected to the rear wall 144, and the rotational axis is defined to pass through the front wall 142 and the rear wall 144. The peripheral wall 146 is oriented around the rotational axis.

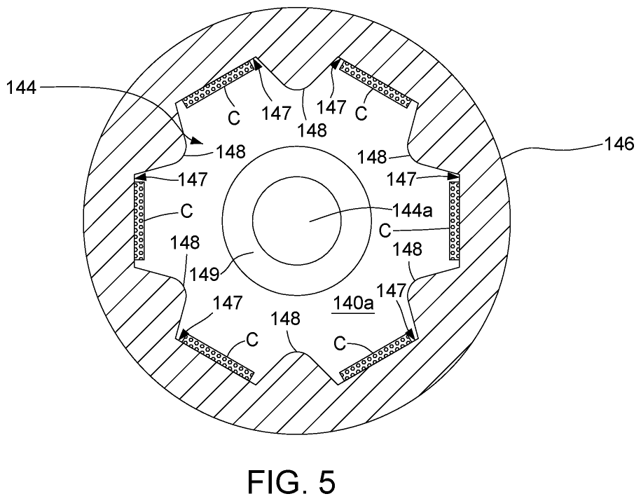

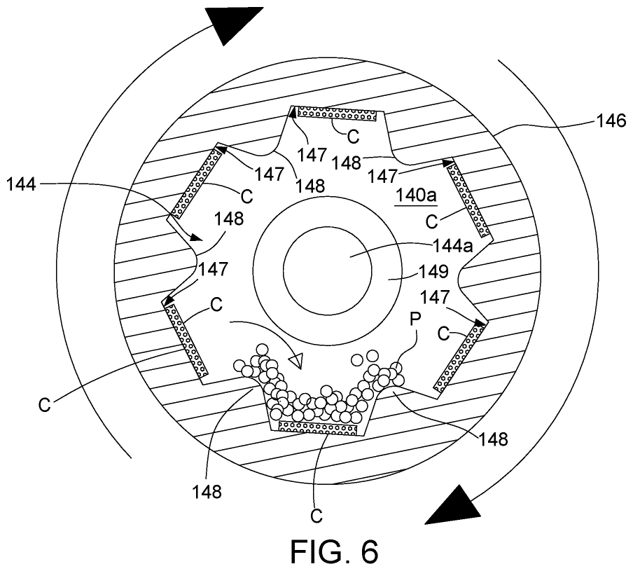

As shown in FIG. 5 and FIG. 6, Concave portions 147 and convex portions 148 are provided on an inner side of the peripheral wall 146 in a staggered configuration. The bottom of each of the concave portions 147 is a planar surface. The concave portions 147 and the convex portions 148 are arranged in a radial arrangement around the rotational axis. Each of the concave portions 147 is for a panel C to be processed to be placed thereon, such that atomic layer deposition of multiple substrates C is able to be processed at the same time in a batch manner.

As shown in FIG. 1 and FIG. 2, the base 110 includes a setup surface 112 for the other components to be disposed thereon. The base 110 may be a separate plate, removably mounted to a work platform. Or, the base 110 may be part of the work platform.

As shown in FIG. 2 and FIG. 3, one end of the shaft seal device 130 is connected to the rear wall 144 of the vacuum chamber 140 along the rotational axis. The rotary drive assembly 120 is connected to the other end of the shaft seal device 130. Specifically, the shaft seal device 130 includes an outer shaft tube 132 and a center shaft tube 134. The outer shaft tube 132 is rotatably disposed on the setup surface 112 of the base 110 via of a bearing seat 114, and the rotary drive assembly 120 is disposed on the setup surface 112. The outer shaft tube 132 includes a first end 132a, a second end 132b, and an accommodation space 132c. Specifically, the outer shaft tube 132 is a hollow column. The rotary drive assembly 120 directly or indirectly connected to the first end 132a of the outer shaft tube 132, and the second end 132b of the outer shaft tube 132 is connected to a rear wall 144 of the vacuum chamber 140, such that the rotary drive assembly 120 is connected to the vacuum chamber 140 via the shaft seal device 130. The rotary drive assembly 120 is configured to drive the outer shaft tube 132 to rotate, so as to drive the vacuum chamber 140 to rotate about the rotational axis.

In detail, the vacuum chamber 140 includes a chamber body 140b and a cover 140c. The chamber body 140b includes the rear wall 144 and peripheral wall 146. The peripheral wall 146 extends over the edge of the rear wall 144 to form an opening. The cover 140c is configured to cover the opening to serve as the front wall 142, so as to define the reaction space 140a between the chamber body 140b and the cover 140c.

The aforementioned powder P may be quantum dots, such as II-VI semiconductor materials such including ZnS, CdS, CdSe, etc., and the film formed on the quantum dots may be aluminum trioxide (Al₂O₃). The selection of materials described above is only an example of this disclosure.

As shown in FIG. 2 and FIG. 3, the center shaft tube 134 has a tubular space 134a, and the plurality of pipelines 150 extend in the tubular space 134a. The center shaft tube 134 is disposed in the accommodation space 132c of the outer shaft tube 132, and the outer shaft tube 132 and the center shaft tube 134 are coaxially disposed in the rotational axis. The center shaft tube 134 is stationary, the rotary drive assembly 120 is not connected to the center shaft tube 134, and the outer shaft tube 132 and the center shaft tube 134 are not fixedly connected. Therefore, the center shaft tube 134 does not rotate with the outer shaft tube 132. For example, the center shaft tube 134 is directly or indirectly fixed to the base 110, and the outer shaft tube 132 rotatably sleeved over the center shaft tube 134. The stationary center shaft tube 134 helps maintain the stability of the plurality of pipelines 150.

As shown in FIG. 1 and FIG. 2, the second end 132b of the outer shaft tube 132 is vertically connected to the rear wall 144, such that the rotary drive assembly 120 is able to drive the vacuum chamber 140 to rotate about the rotational axis via the outer shaft tube 132.

As shown in FIG. 2, the rear wall 144 is provided with a through hole 144a. The center shaft tube 134 protrudes from the second end 132b of the outer shaft tube 132 and is inserted into the through hole 144a to form a rotary seal with the vacuum chamber 140. In detail, one or more shaft seals 160 are provided between the center shaft tube 134 and the outer shaft tube 132. Each of the shaft seals 160 can be a mechanical shaft seal or a magnetic fluid shaft seal, for enhancing the airtightness of the reaction space 140a and prevent the gap between the center shaft tube 134 and the through hole 144a from affecting the airtightness of the reaction space 140a.

As shown in FIG. 1 and FIG. 2, in detail, the rotary drive assembly 120 includes a motor 122 and a transition member 124. The motor 122 is fixed on the setup surface 112 of the base 110, and the motor 122 is connected to the outer shaft tube 132 of the shaft seal device 130 through the transmission member 124. In one example, the transmission member 124 includes a driving gear connected to the motor 122 and a driven gear arranged on the outer shaft tube 132. The driving gear engages with the driven gear, so that the motor 122 drives the outer shaft tube 132 through the transmission member 124 to drive the vacuum chamber 140 to rotate. The combination of the transmission member 124 does not exclude other combinations, such as a combination of a belt and pulleys coupled to the motor 122 and outer shaft tube 132. In yet another example, the transition member 124 is omitted, and the motor 122 is directly connected to the outer shaft tube 132. In this disclosure, the rotary drive assembly 120 drives the outer shaft tube 132 to rotate, and the vacuum chamber 140 is driven to rotate in the same direction, such as clockwise or counterclockwise.

As shown in FIG. 2 and FIG. 3, the plurality of pipelines 150 extend in the tubular space 134a of the center shaft tube 134 and fluidly connected to the reaction space 140a. The plurality of pipelines 150 include a gas evacuating pipeline 152, a reactive gas pipeline 154, and a purge pipeline 156 fluidly connected to the reaction space 140a of the vacuum chamber 140.

As shown in FIG. 2 and FIG. 3, The gas evacuating pipeline 152 is configured to connected to an external air evacuating pump, and the gas evacuating pipeline 152 is fluidly connected to the reaction space 140a of the vacuum chamber 140, such that the air evacuating pump is able to evacuating air from the reaction space 140a, to remove gas in the reaction space 140a for performing the subsequent atomic layer deposition process.

As shown in FIG. 2 and FIG. 3, The reactive gas pipeline 154 is fluidly connected to the reaction space 140a of the vacuum chamber 140, and is configured to transport the reactive gas containing reactants (starting materials/precursors) to the reaction space 140a, to have the reactants (starting materials/precursors) to be adsorbed on the surface of the powder P. The reactive gas may include an inert gas (such as nitrogen) as a carrier and a starting material/precursor blown by the inert gas; or, the main component of the reactive gas itself is the reactant (starting material/precursor). In practical applications, the reactive gas pipeline 154 continuously transports the reactive gas into the reaction space 140a, and the air evacuating pump continues to evacuating air through the gas evacuating pipeline 152 to remove unreacted precursor gas in the reaction space 140a. The apparatus 100 may equipped with plural reactive gas pipelines 154, and each of the reactive gas pipelines 154 respectively transports reactive gases containing different reactants.

As shown in FIG. 2 and FIG. 3, the purge pipeline 156 is fluidly connected to the reaction space 140a of the vacuum chamber 140 and is configured to transport inert gas that does not participate in the reaction as a purge gas, such as nitrogen, to the reaction space 140a. The purge gas creates a flow field of powder P in the reaction space 140a to blow the powder P in the reaction space 140a, and with the rotation drive assembly 120 driving the vacuum chamber 140 to rotate the powder P in the reaction space 140a is effectively and uniformly stirred. Therefore, a thin film of uniform thickness is able to deposit on the surface of each powder P particle. In addition, the flow rate of the gas delivered by the reactive gas pipeline 154 to the reaction space 140a can be increased, and the powder P in the reaction space 140a can be blown through the gas, so that the powder P is driven by the gas and diffuses to various areas of the reaction space 140a. In addition, the purge pipeline 156 can be omitted, and by directly increasing the flow rate of the reactive gas delivered by the reactive gas pipe 154, the powder P flow field can be create by the reactive gas.

Furthermore, the batch type panel atomic layer deposition apparatus 100 further includes a temperature sensor 158 and a heater 159. The temperature sensor 158 may be a thermocouple disposed in the tubular space 134a of the center shaft tube 134. The heater 159 is also disposed in the tubular space 134a for heating the tubular space 134a to adjust the gas temperature in the plurality of pipelines 150. The temperature sensor 158 is configured to detect the temperature of the heater 159 or the tubular space 134a to monitor the working status of the heater 159, thereby adjusting the heating power of the heater 159.

As shown in FIG. 5, the panel C to be processed may be an LED substrate or a LED chip, and the panel C to be processed is placed on the planar surface of one of the concave portions 147. By driving the vacuum chamber 140 to rotate through the rotary drive assembly 120 and the shaft seal device 130, the reactant (precursor/starter) can be deposited and attached to the surface of the panel C to be processed to form a thin film. At the same time, the powder P particles continues to fall under the influence of gravity, and falls on the panel C that is moved below to be processed. The reactant can effectively adsorb the powder P and form a thin film with powder P particles.

Meanwhile, during the rotation of the vacuum chamber 140, the convex portions 148 that continuously move in the circumferential direction also stir the powder P and lift the powder P in the reaction space 140a, so that the powder P can be more fully spread without accumulating at specific locations on the peripheral wall 146.

As shown in FIG. 2, in one example of this disclosure, a filter 134b is provided at one end of the center shaft tube 134 connected to the reaction space 140a, in which the gas evacuating pipeline 152 is fluidly connected to the reaction space 140a through the filter 134b, and extracts the gas within the reaction space 140a through the filter 134b. The filter 134b is mainly used to block the powder P in the reaction space 140a, to prevent the powder P from entering the gas evacuating pipeline 152 and causing the loss of the powder P during the air evacuating.

In order to prevent the powder P stirred by the convex portions 148 from accumulating in the filter 134b in large quantities and clogging the filter 134b, the vacuum chamber 140 further includes a enclosing wall 149. The enclosing wall 149 is disposed on a side of the reaction space 140a where the rear wall 144 is disposed and surrounds the through hole 144a. The enclosing wall 149 shields the through hole 144a in the radial direction of the through hole 144a, thereby preventing the stirred powder P from falling directly into the through hole 144a and clogging the filter 134b.

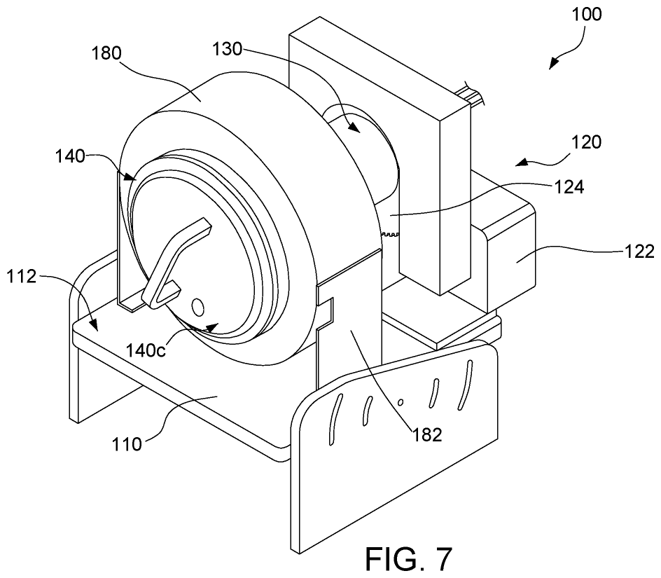

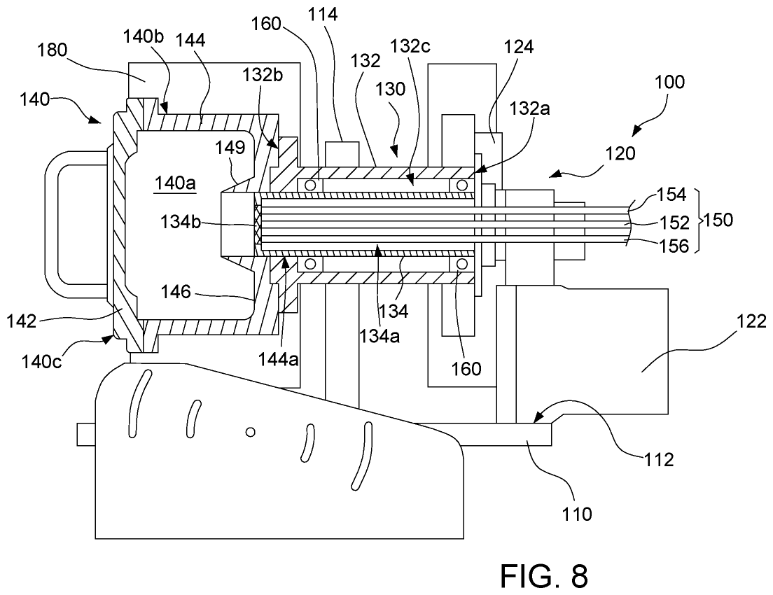

As shown in FIG. 7 and FIG. 8, in order to maintain the temperature in the reaction space 140a, the batch type panel atomic layer deposition apparatus 100 further includes a heating device 180 disposed outside the peripheral wall 146 of the vacuum chamber 140. Specifically, the heating device 180 is annular and is arranged around the outside of the peripheral wall 146. The body of the heating device 180 may be made of metal, with a heating coil or heating rod embedded inside. The heating device 180 is configured to heat the vacuum chamber 140 and the reaction space 140a. In one embodiment of this disclosure, the heating device 180 can be connected to the base 110 through the connecting frame 182, and the rotary drive assembly 120 drives the vacuum chamber 140 to rotate relative to the heating device 180 through the shaft seal device 130.

With the batch type panel atomic layer deposition apparatus of this disclosure 100, it is possible to perform batch atomic layer thin film deposition on multiple panels C to be processed at the same time. The powder C used to form part of the film can be effectively agitated and dispersed in the reaction space 140a to form a film of uniform thickness on the surfaces of the panels C to be processed.

What is claimed is:

1. A batch type panel atomic layer deposition apparatus, comprising:
a vacuum chamber, including a front wall, a rear wall, and a peripheral wall; wherein the front wall and the rear wall are disposed parallel to each other, the peripheral wall connects edges of the front wall and the rear wall to form a reaction space therebetween; concave portions and convex portions are provided on an inner side of the peripheral wall in a staggered configuration; the concave portions and the convex portions are arranged in a radial arrangement around a rotational axis, the bottom of each of the concave portions is a planar surface; and the rotational axis is defined to pass through the front wall an rear wall,
a shaft seal device, having one end connected to the rear wall along the rotational axis; and
a rotary drive assembly, connected to the other end of the shaft seal device, such that the rotary drive assembly is connected to the vacuum chamber through the shaft seal device to drive the vacuum chamber to rotate about the rotational axis.

2. The batch type panel atomic layer deposition apparatus according to claim 1, further comprising: a base, including a setup surface; wherein the rotary drive assembly is disposed on the setup surface.

3. The batch type panel atomic layer deposition apparatus according to claim 1, further comprising: a plurality of pipelines, extending in the shaft seal device, and fluidly connected to the vacuum chamber; wherein the plurality of pipelines are stationary and without rotating with the vacuum chamber.

4. The batch type panel atomic layer deposition apparatus according to claim 2, wherein: the shaft seal device comprising:
an outer shaft tube, rotatably disposed on the setup surface via of a bearing seat, wherein the outer shaft tube includes a first end, a second end, and an accommodation space; the rotary drive assembly is connected to the first end of the outer shaft tube, and the second end of the outer shaft tube is connected to a rear wall of the vacuum chamber, such that the rotary drive assembly is connected to the rear wall of the vacuum chamber through the outer shaft tube to drive the vacuum chamber to rotate; and
a center shaft tube, having a tubular space in which the plurality of pipelines extend;
wherein the center shaft tube is disposed in the accommodation space, the outer shaft tube and the center shaft tube are coaxially disposed in the rotational axis, and the center shaft tube is stationary without rotating with the outer shaft tube.

5. The batch type panel atomic layer deposition apparatus according to claim 4, wherein the rear wall is provided with a through hole; the center shaft tube protrudes from the second end of the outer shaft tube and is inserted into the through hole to form a rotary seal with the vacuum chamber, and at least one shaft seal is provided between the center shaft tube and the outer shaft tube.

6. The batch type panel atomic layer deposition apparatus according to claim 4, wherein the plurality of pipelines include:
a gas evacuating pipeline, fluidly connected to the reaction space, and configured to remove gas from the reaction space;
a reactive gas pipeline, fluidly connected to the reaction space, and configured to transport reactive gas containing reactants to the reaction space; and
a purge pipeline, fluidly connected to the reaction space, and configured to transport non-participating inert gas as purge gas into the reaction space.

7. The batch type panel atomic layer deposition apparatus according to claim 6, further comprising a filter provided at the end of the center shaft tube connected to the reaction space, the gas evacuating pipeline is fluidly connected to the reaction space via the filter, and evacuate gas from the reaction space via the filter.

8. The batch type panel atomic layer deposition apparatus according to claim 7, wherein the vacuum chamber includes an enclosing wall disposed on a side of the reaction space where the rear wall is disposed and surrounds the through hole.

9. The batch type panel atomic layer deposition apparatus according to claim 8, further comprising:
a heater, disposed in the tubular space for heating the tubular space; and
a temperature sensor, disposed in the tubular space and configured to detect a temperature of the heater or the tubular space, so as to adjust a heating power of the heater.

10. The batch type panel atomic layer deposition apparatus according to claim 1, further comprising: a heating device provided around an outside of the peripheral wall and configured to heat the vacuum chamber and the reaction space.
